(19) United States
(12) Patent Application Publication
(10) Pub. No.: US 2025/0194363 A1
(43) Pub. Date: Jun. 12, 2025

(54) DISPLAY DEVICE AND ELECTRONIC DEVICE INCLUDING THE SAME

(71) Applicant: Samsung Display Co., LTD., Yongin-si (KR)

(72) Inventors: JOONYONG PARK, Yongin-si (KR); SUKYOUNG YANG, Yongin-si (KR); DONGMIN LEE, Yongin-si (KR)

(21) Appl. No.: 18/972,275

(22) Filed: Dec. 6, 2024

(30) Foreign Application Priority Data
Dec. 7, 2023 (KR) 10-2023-0176357

(51) Int. Cl. H10K 59/131

(52) U.S. Cl. CPC H10K 59/131

(57) ABSTRACT

A display device includes a first base substrate including a display area in which pixels are disposed and a pad area spaced apart from the display area, an intermediate metal layer disposed on the first base substrate, a second base substrate disposed on the intermediate metal layer, a chip on film in contact with the intermediate metal layer in the pad area, and a connecting electrode disposed on the second base substrate, in contact with the intermediate metal layer in the pad area, and including a first layer including an aluminum alloy and a second layer disposed on the first layer and including aluminum.

This application claims priority to Korean Patent Application No. 10-2023-0176357, filed on Dec. 7, 2023, and all the benefits accruing therefrom under 35 U.S.C. § 119, the content of which in its entirety is herein incorporated by reference.

### BACKGROUND

### 1. Technical Field

The invention relates to a display device and an electronic device including the display device, and more particularly a display device having an improved quality and an electronic device including the display device.

### 2. Description of the Related Art

Generally, a display device is a device that displays an image for providing visual information to a user. Among display devices, an organic light emitting diode display has recently attracted attention.

The display device may include a display panel and a driving chip that transmits a signal to the display panel. As a substrate is bent in a thickness direction in a bending area, the driving chip may be disposed under the display panel. In this case, a dead space of the display device may increase.

### SUMMARY

Embodiments provide a display device with improved quality.

Embodiments provide an electronic device including the display device.

A display device, according to an embodiment, includes a first base substrate including a display area in which pixels are disposed and a pad area which is spaced apart from the display area, an intermediate metal layer disposed on the first base substrate, a second base substrate disposed on the intermediate metal layer, a chip on film in contact with the intermediate metal layer in the pad area, and a connecting electrode disposed on the second base substrate, in contact with the intermediate metal layer in the pad area, and including a first layer including an aluminum alloy and a second layer disposed on the first layer and including aluminum.

In an embodiment, the aluminum alloy included in the first layer of the connecting electrode may include nickel (“Ni”).

In an embodiment, the aluminum alloy included in the first layer of the connecting electrode may further include neodymium (“Nd”).

In an embodiment, the aluminum alloy included in the first layer of the connecting electrode may further include lanthanum (“La”).

In an embodiment, a ratio of the nickel in the aluminum alloy included in the first layer of the connecting electrode may be equal to or greater than about 0.02 atomic percent and equal to or less than about 0.05 atomic percent.

In an embodiment, a ratio of the neodymium in the aluminum alloy included in the first layer of the connecting electrode may be equal to or greater than about 0.02 atomic percent and equal to or less than about 0.05 atomic percent.

In an embodiment, a ratio of the lanthanum in the aluminum alloy included in the first layer of the connecting electrode may be equal to or greater than about 0.02 atomic percent and equal to or less than about 0.05 atomic percent.

In an embodiment, a thickness of the first layer of the connecting electrode may be equal to or greater than about 3000 angstroms and equal to or less than about 4000 angstroms.

In an embodiment, the connecting electrode may further include a third layer disposed on the second layer and including an aluminum alloy.

In an embodiment, the aluminum alloy included in the third layer of the connecting electrode may include at least one of nickel, neodymium, and lanthanum.

In an embodiment, a ratio of the nickel in the aluminum alloy included in the third layer of the connecting electrode may be equal to or greater than about 0.02 atomic percent and equal to or less than about 0.05 atomic percent.

In an embodiment, a ratio of the neodymium in the aluminum alloy included in the third layer of the connecting electrode may be equal to or greater than about 0.02 atomic percent and equal to or less than about 0.05 atomic percent.

In an embodiment, a ratio of the lanthanum in the aluminum alloy included in the third layer of the connecting electrode may be equal to or greater than about 0.02 atomic percent and equal to or less than about 0.05 atomic percent.

In an embodiment, a thickness of each of the first layer of the connecting electrode and the third layer of the connecting electrode may be equal to or greater than about 2000 angstroms and equal to or less than about 3000 angstroms.

In an embodiment, the connecting electrode may further include a fourth layer disposed under the first layer and including titanium.

In an embodiment, the connecting electrode may further include a fifth layer disposed on the second layer and including titanium.

In an embodiment, the first base substrate may define a first opening in a partial area of the pad area.

In an embodiment, the chip on film may be in contact with a lower surface of the intermediate metal layer in the first opening.

In an embodiment, each of the pixels may include an active layer disposed on the second base substrate, a gate electrode disposed on the active layer, a source electrode disposed on the gate electrode, and a drain electrode disposed on the gate electrode and spaced apart from the source electrode.

In an embodiment, the connecting electrode, the source electrode and the drain electrode may be disposed on the same layer.

In an embodiment, the connecting electrode may contact an upper surface of the intermediate metal layer.

In an embodiment, the second base substrate may include polyimide.

In an embodiment, the first base substrate and the second base substrate may include the same material.

In an embodiment, the second base substrate may define a second opening.

In an embodiment, the connecting electrode may contact the intermediate metal layer in the second opening.

An electronic device, according to an embodiment, includes a first base substrate including a display area in which pixels are disposed and a pad area which is spaced apart from the display area, an intermediate metal layer disposed on the first base substrate, a second base substrate disposed on the intermediate metal layer, a chip on film in contact with the intermediate metal layer in the pad area, a connecting electrode disposed on the second base substrate, in contact with the intermediate metal layer in the pad area, and including a first layer including an aluminum alloy and a second layer disposed on the first layer and including aluminum, and a memory device configured to store data.

A display device, according to an embodiment, may include a first base substrate including a display area in which pixels are disposed and a pad area which is spaced apart from the display area, an intermediate metal layer disposed on the first base substrate, a second base substrate disposed on the intermediate metal layer, a chip on film in contact with the intermediate metal layer in the pad area, and a connecting electrode disposed on the second base substrate, in contact with the intermediate metal layer in the pad area, and including a first layer including an aluminum alloy and a second layer disposed on the first layer and including aluminum.

Accordingly, a phenomenon that a grain grows abnormally in the connecting electrode may be prevented. Accordingly, a phenomenon in which a surface of the connecting electrode becomes rough may be prevented, and a phenomenon in which black points are visually recognized in a partial area of the connecting electrode may be prevented.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device, according to an embodiment.

FIG. 2 is a cross-sectional view of the display device of FIG. 1 taken along the X-Y line, according to an embodiment.

FIG. 3 is an enlarged cross-sectional view of area A of FIG. 2, according to an embodiment.

FIG. 4 is an enlarged cross-sectional view of an example of area B of FIG. 3, according to an embodiment.

FIG. 5 is a cross-sectional view illustrating a pixel included in the display device of FIG. 1, according to an embodiment.

FIG. 6 is an enlarged cross-sectional view of another example of area B of FIG. 3, according to an embodiment.

FIG. 7 is a block diagram illustrating an electronic device according to embodiments.

FIG. 8 is a diagram illustrating an example in which the electronic device of FIG. 7 is implemented as a smart phone.

### DETAILED DESCRIPTION OF THE EMBODIMENTS

Hereinafter, display devices in accordance with embodiments will be described in more detail with reference to the accompanying drawings. The same reference numerals are used for the same components in the drawings, and redundant descriptions of the same components will be omitted.

It will be understood that when an element (or a region, a layer, a portion, or the like) is referred to as being related to another such as being “on”, “connected to” or “coupled to” another element, it may be directly disposed on, connected or coupled to the other element, or intervening elements may be disposed therebetween.

Like reference numerals or symbols refer to like elements throughout. In the drawings, the thickness, the ratio, and the size of the element are exaggerated for effective description of the technical contents. As used herein, the term “and/or” includes any and all combinations of one or more of the associated listed items.

The term “and/or,” may include all combinations of one or more of which associated configurations may define.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the inventive concept. Similarly, a second element, component, region, layer or section may be termed a first element, component, region, layer or section. As used herein, the singular forms, “a”, “an” and “the” are intended to include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described on the basis of the directions indicated in the drawings.

It will be further understood that the terms “comprise”, “includes” and/or “have”, when used in this specification, specify the presence of stated features, integers, steps, operations, elements, components, and/or groups thereof, but do not preclude the presence or addition of one or more other features, integers, steps, operations, elements, components, and/or groups thereof. As used herein, being “disposed directly on” may mean that there is no additional layer, film, region, plate, or the like between a part and another part such as a layer, a film, a region, a plate, or the like. For example, being “disposed directly on” may mean that two layers or two members are disposed without using an additional member such as an adhesive member, therebetween.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

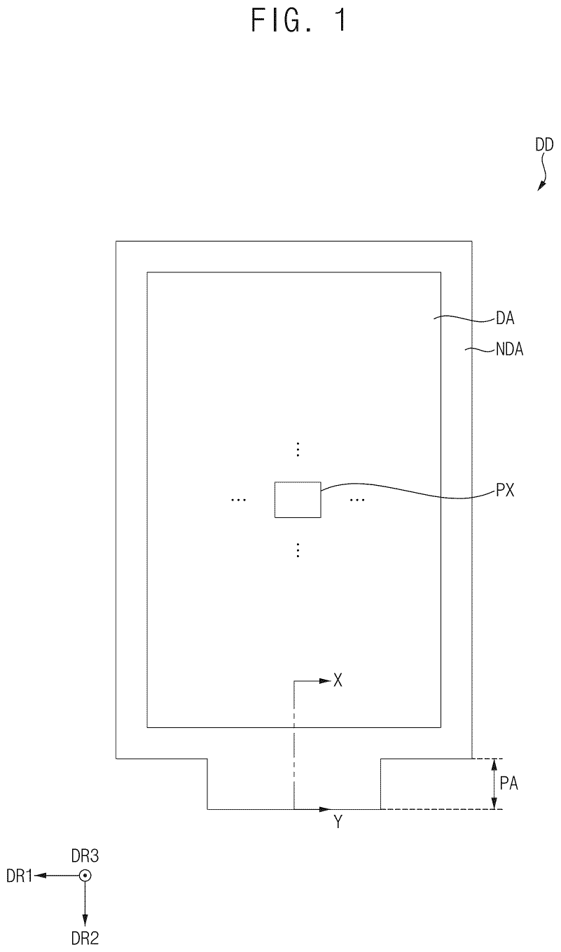

FIG. 1 is a plan view illustrating a display device, according to an embodiment.

In an embodiment and referring to FIG. 1, a display device DD may include a display area DA and a non-display area NDA. The display area DA may be defined as an area that emits light, and the non-display area NDA may be defined as an area in which components for transmitting signals to the display area DA are disposed.

In an embodiment, pixels PX may be disposed in the display area DA. Each of the pixels PX may emit light based on a signal applied from the non-display area NDA. The pixels PX may be generally disposed in the display area DA and directed along a first direction DR1 and a second direction DR2 crossing the first direction DR1. Accordingly, the display area DA may emit light and display an image over the entire area.

In an embodiment, the non-display area NDA may be disposed adjacent to the display area DA. For example, the non-display area NDA may be disposed around the display area DA. For example, the non-display area NDA may surround at least a portion of the display area DA. The non-display area NDA may include the pad area PA. The pad area PA may be spaced apart from the display area DA. For example, the pad area PA may be spaced apart from one side of the display area DA in the second direction DR2.

In an embodiment, the non-display area NDA may include a plurality of drivers for driving the pixels PX. For example, the plurality of drivers may include a gate driver, a light emitting driver, a power voltage generator, a timing controller, and the like.

For example, in an embodiment, the second direction DR2 may be directed to be perpendicular to the first direction DR1. However, this invention is not limited thereto, and the second direction DR2 may form an acute angle or an obtuse angle with the first direction DR1. In addition, a third direction DR3 intersecting a plane formed by the first direction DR1 and the second direction DR2 may be defined. For example, the third direction DR3 may be directed to be perpendicular to the plane formed by the first direction DR1 and the second direction DR2. However, this invention is not limited thereto, and the third direction DR3 may form an acute angle or an obtuse angle with the plane formed by the first direction DR1 and the second direction DR2.

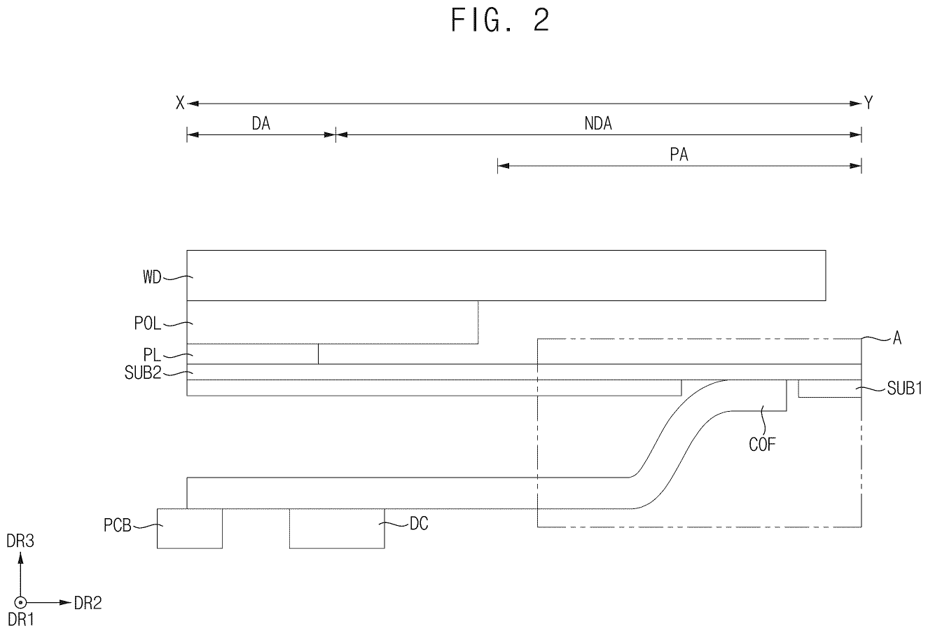

FIG. 2 is a cross-sectional view of the display device of FIG. 1 taken along the X-Y line, according to an embodiment.

In an embodiment and referring to FIGS. 1 and 2, the display device DD may include a first base substrate SUB1, a second base substrate SUB2, a display layer PL, a polarizing plate POL, a cover window WD, a chip on film COF, a driving chip DC, and a circuit board PCB.

In an embodiment, the first base substrate SUB1 may include a transparent material or an opaque material. For example, the first base substrate SUB1 may be formed of a transparent resin substrate. For example, the first base substrate SUB1 may include polyimide.

However, this invention is not limited thereto, and in another embodiment, the first base substrate SUB1 may include a quartz substrate (for example, a synthetic quartz substrate, a fluorine-doped quartz substrate), a calcium fluoride substrate, a soda-lime glass substrate, a non-alkali glass substrate, or the like. These materials may be used alone or in combination with each other.

For example, in an embodiment, the first base substrate SUB1 may include the display area DA in which pixels PX are disposed and the non-display area NDA including the pad area PA.

In an embodiment, the second base substrate SUB2 may be disposed on the first base substrate SUB1. The second base substrate SUB2 may include a transparent material or an opaque material. For example, in an embodiment, the second base substrate SUB2 may be formed of a transparent resin substrate. For example, in an embodiment, the second base substrate SUB2 may include polyimide.

However, this invention is not limited thereto, and in an embodiment, the second base substrate SUB2 may include a quartz substrate (for example, a synthetic quartz substrate, a fluorine-doped quartz substrate), a calcium fluoride substrate, a soda-lime glass substrate, a non-alkali glass substrate, or the like. These materials may be used alone or in combination with each other.

In an embodiment, the second base substrate SUB2 and the first base substrate SUB1 may include substantially the same material. However, this invention is not limited thereto, and in another embodiment, the second base substrate SUB2 and the first base substrate SUB1 may include different materials.

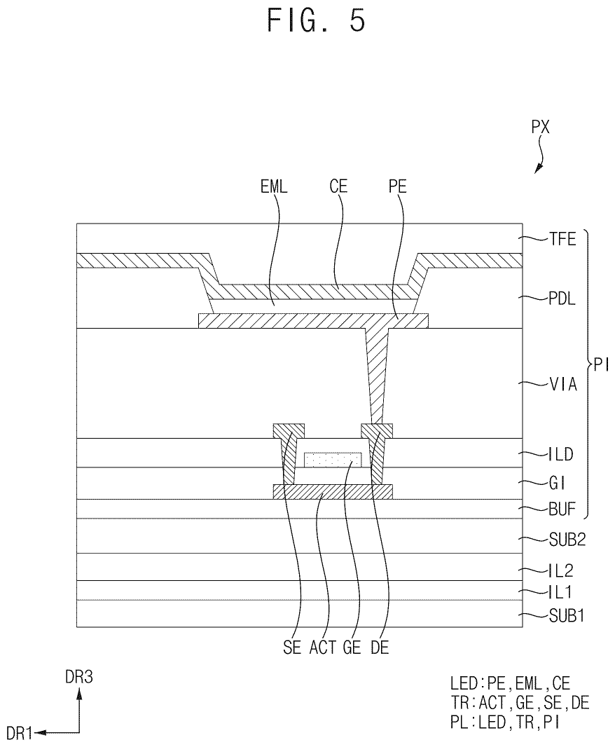

In an embodiment, the display layer PL may be disposed on the second base substrate SUB2. The display layer PL may be disposed in at least a portion of the display area DA. The display layer PL will be described in more detail with reference to FIG. 5.

In an embodiment, the polarizing plate POL may be disposed on the display layer PL. The polarizing plate POL may prevent external light from being reflected. For example, the external light may pass through the polarizing plate POL and be reflected from an upper surface of a common electrode (for example, a common electrode CE of FIG. 5). Thereafter, the external light may pass through the polarizing plate POL again, and in this case, a phase of the external light may be changed. As a result, a phase of the light reflected from the common electrode and a phase of the external light incident on the polarizing plate POL are different, extinction interference may occur between the reflected light and the external light incident on the polarizing plate POL.

In an embodiment, the cover window WD may be disposed on the polarizing plate POL. The cover window WD may protect the display layer PL, the polarizing plate POL, and the like, from an external impact. For example, the cover window WD may be attached to the polarizing plate POL through a separate adhesive layer. For example, the cover window WD may be attached to the polarizing plate POL through an optically clear adhesive (“OCA”), an optically clear resin (“OCR”), a pressure sensitive adhesive (“PSA”), or the like.

In an embodiment, the chip on film COF may be disposed under the second base substrate SUB2. For example, the chip on film COF may be disposed in the pad area PA. Signal lines for applying an electrical signal to the pixels PX may be disposed on the chip on film COF.

For example, in an embodiment, the chip on film COF may include a flexible material (film, tape, or the like.). Accordingly, the chip on film COF may be bent in various shapes under the second base substrate SUB2.

In an embodiment, the driving chip DC may be disposed on the chip on film COF. The driving chip DC may convert a digital data signal among driving signals into an analog data signal. In addition, the driving chip DC may provide the analog data signal to the pixels PX. That is, the driving chip DC may provide the analog data signal to the pixels PX through the signal lines disposed on the chip on film COF.

In an embodiment, the driving chip DC may be attached to the second base substrate SUB2 in a chip on film (“COF”) scheme. However, this invention is not limited thereto, and in another embodiment, the driving chip DC may be directly attached to the second base substrate SUB2 in a chip on plastic (“COP”) scheme or chip on glass (“COG”) scheme.

In an embodiment, the circuit board PCB may be disposed on the chip on film COF. The circuit board PCB may be spaced apart from the driving chip DC. For example, the circuit board PCB may be spaced apart from the driving chip DC in a direction opposite to the second direction DR2 on the chip on film COF. The circuit board PCB may apply a driving signal, a driving voltage, and the like to the driving chip DC and the pixels PX.

In an embodiment, each of the first base substrate SUB1 and the second base substrate SUB2 may not be bent. In addition, the chip on film COF may be attached to an lower surface of the second base substrate SUB2. In addition, the driving chip DC and the circuit board PCB may be disposed on the chip-on film COF. Accordingly, a dead space of the display device DD may be reduced.

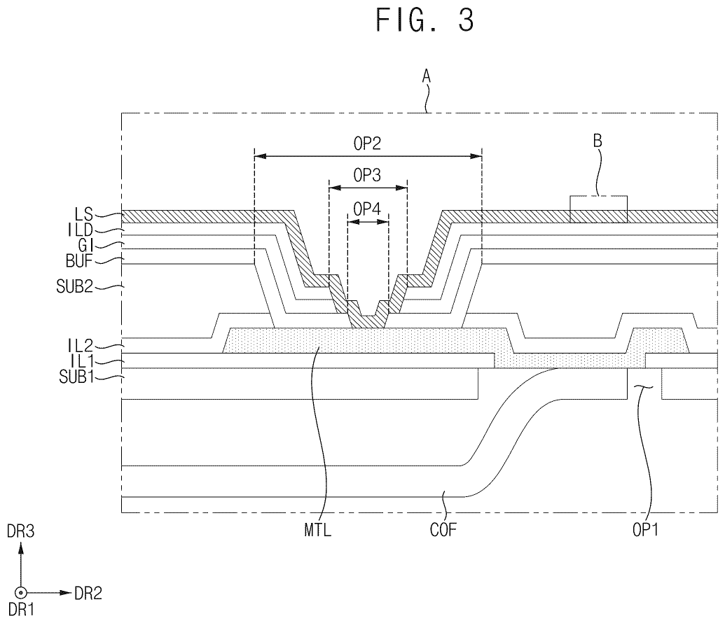

FIG. 3 is an enlarged cross-sectional view of area A of FIG. 2, according to an embodiment.

In an embodiment and referring to FIGS. 2 and 3, the first base substrate SUB1 may define a first opening OP1. For example, the first base substrate SUB1 may define the first opening OP1 in a partial area of the pad area PA. For example, the first opening OP1 may be a portion removed from the lower surface of the first base substrate SUB1 to the upper surface of the first base substrate SUB1.

In an embodiment, the chip on film COF may be in contact with a lower surface of the intermediate metal layer MTL, which will be described later, in the first opening OP1. That is, as the first base substrate SUB1 defines the first opening OP1, a space in which the intermediate metal layer MTL and the chip on film COF are in contact may be formed.

In an embodiment, a first insulating layer IL1 may be disposed on the first base substrate SUB1. The first insulating layer IL1 may define an opening. The opening of the first insulating layer IL1 may overlap the first opening OP1 in a plan view. The intermediate metal layer MTL may fill the opening of the first insulating layer IL1. Accordingly, the intermediate metal layer MTL may be connected to the chip on film COF.

For example, in an embodiment, the first insulating layer IL1 may include an inorganic material. For example, the first insulating layer IL1 may include an inorganic material such as silicon oxide, silicon nitride, silicon oxynitride, or the like. These materials may be used alone or in combination with each other.

In an embodiment, the second insulating layer IL2 may be disposed on the first insulating layer IL1. The second insulating layer IL2 may include an inorganic material. For example, the second insulating layer IL2 may include an inorganic material such as silicon oxide, silicon nitride, silicon oxynitride, or the like. These materials may be used alone or in combination with each other.

In an embodiment, the second base substrate SUB2 may be disposed on the second insulating layer IL2. The second insulating layer IL2 and the second base substrate SUB2 may define a second opening OP2. An upper surface of the intermediate metal layer MTL may be exposed through the second opening OP2.

In an embodiment, the intermediate metal layer MTL may be disposed on the first base substrate SUB1. In addition, the second base substrate SUB2 may be disposed on the intermediate metal layer MTL. That is, the intermediate metal layer MTL may be disposed between the first base substrate SUB1 and the second base substrate SUB2. For example, the intermediate metal layer MTL may be disposed between the first insulating layer IL1 and the second insulating layer IL2. As described above, the intermediate metal layer MTL may fill the opening of the first insulating layer IL1. In addition, the lower surface of the intermediate metal layer MTL may be in contact with the chip on film COF in the first opening OP1.

For example, in an embodiment, the intermediate metal layer MTL may include a metal, a conductive metal oxide, a metal nitride, or the like. These materials may be used alone or in combination with each other.

In an embodiment, examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other.

In an embodiment, examples of the conductive metal oxide may include indium tin oxide, indium zinc oxide, or the like. These materials may be used alone or in combination with each other.

In addition, in an embodiment, examples of the metal nitride may include aluminum nitride (“AlNₓ”), tungsten nitride (“WNₓ”), chromium nitride (“CrNₓ”), or the like. These materials may be used alone or in combination with each other.

In an embodiment, a buffer layer BUF may be disposed on the second base substrate SUB2. The buffer layer BUF may cover the upper surface of the intermediate metal layer MTL exposed through the second opening OP2. In addition, the buffer layer BUF may define the fourth opening OP4. The fourth opening OP4 may overlap the second opening OP2 in a plan view. A portion of the upper surface of the intermediate metal layer MTL may be exposed through the fourth opening OP4. In an embodiment, a width of the fourth opening OP4 directed in the second direction DR2 may be less than a width of the second opening OP2 directed in the second direction DR2.

For example, in an embodiment, the buffer layer BUF may include an inorganic material such as silicon oxide, silicon nitride, silicon oxynitride, or the like. These materials may be used alone or in combination with each other.

In an embodiment, a gate insulating layer GI may be disposed on the buffer layer BUF. For example, the gate insulating layer GI may include an inorganic material such as silicon oxide, silicon nitride, silicon oxynitride, or the like. These materials may be used alone or in combination with each other.

In an embodiment, an interlayer insulating layer ILD may be disposed on the gate insulating layer GI. For example, the interlayer insulating layer ILD may include an inorganic material such as silicon oxide, silicon nitride, silicon oxynitride, or the like. These materials may be used alone or in combination with each other.

In an embodiment, the gate insulating layer GI and the interlayer insulating layer ILD may define a third opening OP3. The third opening OP3 may overlap the second opening OP2 in a plan view. A portion of the upper surface of the intermediate metal layer MTL may be exposed through the third opening OP3. For example, a width of the third opening OP3 directed in the second direction DR2 may be smaller than the width of the second opening OP2 directed in the second direction DR2 and may be greater than the width of the fourth opening OP4 directed in the second direction DR2.

In an embodiment, a connecting electrode LS may be disposed on the interlayer insulating layer ILD. The connecting electrode LS may be in contact with the intermediate metal layer MTL in the pad area PA. For example, the connecting electrode LS may be in contact with the intermediate metal layer MTL in the second opening OP2. For example, the connecting electrode LS may be in contact with the upper surface of the intermediate metal layer MTL exposed through the fourth opening OP4.

In an embodiment, the driving chip DC and the circuit board PCB may transmit driving signals to pixels (for example, the pixels PX of FIG. 1) through the chip on film COF, the intermediate metal layer MTL, and the connecting electrode LS.

In an embodiment, the connecting electrode LS, a source electrode (for example, a source electrode SE of FIG. 5) and a drain electrode (for example, a drain electrode DE of FIG. 5) to be described later may be formed on the same layer. In an embodiment, the connecting electrode LS, the source electrode, and the drain electrode may include the same material. However, this invention is not limited thereto, and the connecting electrode LS, the source electrode, and the drain electrode may include different materials.

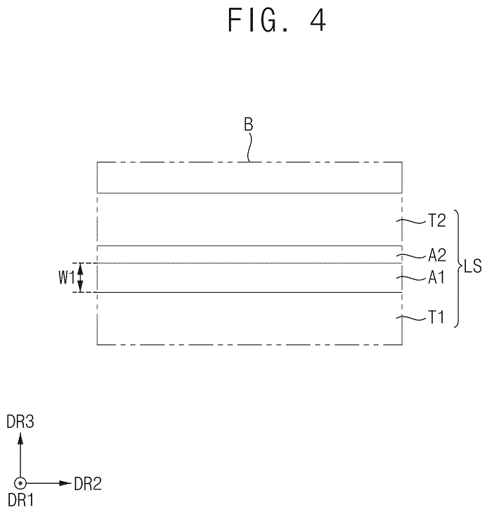

FIG. 4 is an enlarged cross-sectional view of an example of area B of FIG. 3, according to an embodiment.

In an embodiment and referring to FIG. 4, the connecting electrode LS may include a first layer T1, a second layer A1, a third layer A2, and a fourth layer T2. The second layer A1 may be disposed on the first layer T1. The third layer A2 may be disposed on the second layer A1. The fourth layer T2 may be disposed on the third layer A2.

In an embodiment, the first layer T1 may include a metal. In an embodiment, the first layer T1 may include titanium. However, this invention is not limited thereto, and in another embodiment, the first layer T1 may include other kinds of metal materials such as tungsten, copper, nickel, chromium, or the like.

In an embodiment, the second layer A1 may include a metal. In an embodiment, the second layer A1 may include an aluminum alloy. In an embodiment, the aluminum alloy included in the second layer A1 may include aluminum (“Al”) and nickel (“Ni”). In an embodiment, the aluminum alloy included in the second layer A1 may further include neodymium (“Nd”). In an embodiment, the aluminum alloy included in the second layer A1 may further include lanthanum (“La”). However, this invention is not limited thereto, and the aluminum alloy included in the second layer A1 may further include other types of metal materials.

In an embodiment, the third layer A2 may include a metal. In an embodiment, the third layer A2 may include aluminum. For example, the third layer A2 may include pure aluminum. However, this invention is not limited thereto, and in another embodiment, the third layer A2 may include other kinds of metal materials such as tungsten, copper, nickel, chromium, or the like.

In an embodiment, the fourth layer T2 may include a metal. In an embodiment, the fourth layer T2 may include titanium. However, this invention is not limited thereto, and in another embodiment, the fourth layer T2 may include other kinds of metal materials such as tungsten, copper, nickel, chromium, or the like.

In an embodiment, the fourth layer T2 and the first layer T1 may include the same material. However, this invention is not limited thereto, and in another embodiment, the fourth layer T2 and the first layer T1 may include different materials.

In an embodiment, a size of a grain of an aluminum alloy may be smaller than a size of a grain of pure aluminum. Accordingly, the grain of the aluminum alloy may not grow abnormally. In another embodiment, the probability that the grain of the aluminum alloy grows abnormally may be lower than probability that the grain of the pure aluminum grows abnormally.

In an embodiment and as described above, the second layer A1 may include an aluminum alloy. Accordingly, the grain of the second layer A1 may not grow abnormally. In another embodiment, as the second layer A1 contains an aluminum alloy, there may be a higher probability that the grain of the second layer A1 does not grow abnormally than when the second layer A1 contains pure aluminum. That is, as the second layer A1 includes an aluminum alloy, a phenomenon that a grain grows abnormally in the connecting electrode LS may be prevented. Accordingly, a phenomenon in which a surface of the connecting electrode LS becomes rough may be prevented, and a phenomenon in which black points are visually recognized in a partial area of the connecting electrode LS may be prevented.

In an embodiment and as described above, the second base substrate (for example, the second base substrate SUB2 of FIG. 3) may include polyimide. That is, the second base substrate may include an organic material. In this case, outgassing of oxygen and/or moisture may occur in the second base substrate. As the second layer A1 contains the aluminum alloy, a phenomenon in which the oxygen and/or moisture outgassed from the second base substrate penetrates into the third layer A2 including aluminum may be prevented. That is, the second layer A1 may protect the third layer A2 from the oxygen and/or moisture outgassed from the second base substrate. Accordingly, the aluminum included in the third layer A2 may not be oxidized to aluminum oxide or the like. Therefore, a phenomenon in which black points are visually recognized due to a difference in reflectance between the aluminum and the aluminum oxide in the third layer A2 may be prevented.

However, this invention is not limited thereto, and there may be various reasons for the phenomenon in which black points are recognized, and as the second layer A1 includes an aluminum alloy, the phenomenon in which black points are recognized in the connecting electrode LS may be prevented.

In an embodiment, a ratio of the nickel in the aluminum alloy included in the second layer A1 of the connecting electrode LS may be equal to or greater than about 0.02 atomic percent and equal to or less than about 0.05 atomic percent. When the ratio of the nickel in the aluminum alloy included in the second layer A1 is less than about 0.02 atomic percent, a grain of the second layer A1 may grow abnormally, or the probability that the grain of the second layer A1 grows abnormally may increase. When the ratio of the nickel in the aluminum alloy included in the second layer A1 exceeds about 0.05 atomic percent, when the connecting electrode LS including the second layer A1 is formed on the gate insulating layer (for example, the gate insulating layer GI of FIG. 3), an etching process may not proceed smoothly.

In an embodiment, a ratio of the neodymium in the aluminum alloy included in the second layer A1 of the connecting electrode LS may be equal to or greater than about 0.02 atomic percent and equal to or less than about 0.05 atomic percent. When the ratio of the neodymium in the aluminum alloy included in the second layer A1 is less than about 0.02 atomic percent, a grain of the second layer A1 may grow abnormally, or the probability that the grain of the second layer A1 grows abnormally may increase. When the ratio of the neodymium in the aluminum alloy included in the second layer A1 exceeds about 0.05 atomic percent, when the connecting electrode LS including the second layer A1 is formed on the gate insulating layer (for example, the gate insulating layer GI of FIG. 3), an etching process may not proceed smoothly.

In an embodiment, a ratio of lanthanum in the aluminum alloy included in the second layer A1 of the connecting electrode LS may be equal to or greater than about 0.02 atomic percent and equal to or less than about 0.05 atomic percent. When the ratio of the lanthanum in the aluminum alloy included in the second layer A1 is less than about 0.02 atomic percent, a grain of the second layer A1 may grow abnormally, or the probability that the grain of the second layer A1 grows abnormally may increase. When the ratio of the lanthanum in the aluminum alloy included in the second layer A1 exceeds about 0.05 atomic percent, when the connecting electrode LS including the second layer A1 is formed on the gate insulating layer (for example, the gate insulating layer GI of FIG. 3), an etching process may not proceed smoothly.

In an embodiment, a thickness W1 of the second layer A1 of the connecting electrode LS may be equal to or greater than about 3000 angstroms and equal to or less than about 4000 angstroms. When the thickness W1 of the second layer A1 is less than about 3000 angstroms, the second layer A1 may not sufficiently protect the third layer A2 from the oxygen and/or moisture outgassed in the second base substrate. When the thickness W1 of the second layer A1 exceeds about 4000 angstroms, electrical resistance of the connecting electrode LS may increase or electrical conductivity of the connecting electrode LS may decrease.

FIG. 5 is a cross-sectional view illustrating a pixel included in the display device of FIG. 1, according to an embodiment.

In an embodiment and referring to FIG. 5, the pixel PX may include a first base substrate SUB1, a second base substrate SUB2, a first insulating layer IL1, a second insulating layer IL2, a display insulating layer PI, an active layer ACT, a source electrode SE, a gate electrode GE, a drain electrode DE, a pixel electrode PE, a light emitting layer EML, and a common electrode CE.

In an embodiment, a light emitting element LED may include the pixel electrode PE, the light emitting layer EML, and the common electrode CE. A transistor TR may include the active layer ACT, the gate electrode GE, the source electrode SE, and the drain electrode DE. The display layer PL may include the light emitting element LED, the transistor TR, and the display insulating layer PI.

In an embodiment, the display insulating layer PI may include the buffer layer BUF, the gate insulating layer GI, the interlayer insulating layer ILD, a via insulating layer VIA, a pixel defining layer PDL, and an encapsulation layer TFE.

In an embodiment, the active layer ACT may be disposed on the buffer layer BUF. The active layer ACT may include an inorganic semiconductor (e.g., amorphous silicon, polysilicon, a metal oxide semiconductor,), an organic semiconductor, or the like. These materials may be used alone or in combination with each other. The active layer ACT may include a source area, a drain area, and a channel area disposed between the source area and the drain area.

In an embodiment, the metal oxide semiconductor may include a binary compound (“ABₓ”), a ternary compound (“ABₓC_{y}”), a tetragonal compound (“ABₓC_{y}D_{z}”), and the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), or the like. These materials may be used alone or in combination with each other.

For example, in an embodiment, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

In an embodiment, the gate insulating layer GI may be disposed on the buffer layer BUF. The gate insulating layer GI may sufficiently cover the active layer ACT. For example, The gate insulating layer GI may cover the active layer ACT and may be disposed along a profile of the active layer ACT.

In an embodiment, the gate electrode GE may be disposed on the gate insulating layer GI. The gate electrode GE may overlap the channel area of the active layer ACT.

In an embodiment, the gate electrode GE may include a metal, an alloy metal nitride, a conductive metal oxide, a transparent conductive material, or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other.

In an embodiment, examples of the conductive metal oxide may include Indium tin oxide, indium zinc oxide, or the like. In addition, examples of the metal nitride may include aluminum nitride (“AlNₓ”), tungsten nitride (“WNₓ”), chromium nitride (“CrNₓ”), or the like. These materials may be used alone or in combination with each other.

In an embodiment, the interlayer insulating layer ILD may be disposed on the gate insulating layer GI. The interlayer insulating layer ILD may sufficiently cover the gate electrode GE. For example, the interlayer insulating layer ILD may cover the gate electrode GE, and may be disposed along a profile of the gate electrode GE.

In an embodiment, the source electrode SE may be disposed on the interlayer insulating layer ILD. The source electrode SE may be connected to the source area of the active layer ACT through a first contact hole penetrating the gate insulating layer GI and the interlayer insulating layer ILD.

In an embodiment, the drain electrode DE may be disposed on the interlayer insulating layer ILD. The drain electrode DE may be connected to the drain area of the active layer ACT through a second contact hole penetrating the gate insulating layer GI and the interlayer insulating layer ILD.

For example, in an embodiment, each of the source electrode SE and the drain electrode DE may include a metal, an alloy, a metal nitride, a conductive metal oxide, a transparent conductive material, or the like. These materials may be used alone or in combination with each other. In an embodiment, the source electrode SE, the drain electrode DE, and the connecting electrode (for example, the connecting electrode LS of FIG. 4) may include the same material and have the same structure.

However, this invention is not limited thereto, and in another embodiment, each of the source electrode SE and the drain electrode DE may have a material different from the material of the connecting electrode and a structure different from the structure of the connecting electrode. For example, in an embodiment, each of the source electrode SE and the drain electrode DE may have a single layer structure made of one material.

In an embodiment, the via insulating layer VIA may be disposed on the interlayer insulating layer ILD. The via insulating layer VIA may sufficiently cover the source electrode SE and the drain electrode DE. The via insulating layer VIA may include an organic material. For example, the via insulating layer VIA may include organic materials such as phenolic resin, acrylic resin, polyimide resin, polyamide resin, siloxane resin, epoxy resin, or the like. These materials may be used alone or in combination with each other.

In an embodiment, the pixel electrode PE may be disposed on the via insulating layer VIA. The pixel electrode PE may be connected to the drain electrode DE through a contact hole penetrating the via insulating layer VIA.

In an embodiment, the pixel electrode PE may include a metal, an alloy, a metal nitride, a conductive metal oxide, a transparent conductive material, or the like. These materials be used alone or in combination with each other. In an embodiment, the pixel electrode PE may have a stacked structure including ITO/Ag/ITO. For example, in an embodiment, the pixel electrode PE may operate as an anode.

In an embodiment, the pixel defining layer PDL may be disposed on the via insulating layer VIA. The pixel defining layer PDL may cover side portions of the pixel electrode PE. In addition, an opening exposing a portion of the upper surface of the pixel electrode PE may be defined in the pixel defining layer PDL.

For example, in an embodiment, the pixel defining layer PDL may include an inorganic material or an organic material. In an embodiment, the pixel defining layer PDL may include an organic material such as an epoxy resin, a siloxane resin, or the like. These materials may be used alone or in combination with each other. In another embodiment, the pixel defining layer PDL may further include a light blocking material containing a black pigment, a black dye, or the like.

In an embodiment, the light emitting layer EML may be disposed on the pixel electrode PE. The light emitting layer EML may include an organic material that emits light of a predetermined color. For example, the light emitting layer EML may include an organic material that emits red light. However, the invention is not limited thereto, and the light emitting layer EML may emit light of a different color from red light.

In an embodiment, the common electrode CE may be disposed on the light emitting layer EML and the pixel defining layer PDL. The common electrode CE may include a metal, an alloy, a metal nitride, a conductive metal oxide, a transparent conductive material, or the like. These materials may be used alone or in combination with each other. The common electrode CE may operate as a cathode.

In an embodiment, the encapsulation layer TFE may be disposed on the common electrode CE. The encapsulation layer TFE may prevent impurities and moisture from penetrating into the pixel electrode PE, the light emitting layer EML, and the common electrode CE from the outside. The encapsulation layer TFE may include at least one inorganic layer and at least one organic layer.

For example, in an embodiment, the inorganic layer may include silicon oxide, silicon nitride, silicon oxynitride, or the like. These materials may be used alone or in combination with each other. The organic layer may include a polymer cured product such as polyacrylate.

Although an embodiment of the pixel PX has been described with reference to FIG. 5, the pixel PX is not limited to the structure shown in FIG. 5. That is, in other embodiments, the pixel PX may include all structures that receive an electrical signal and emit light having a luminance corresponding to the intensity of the electrical signal.

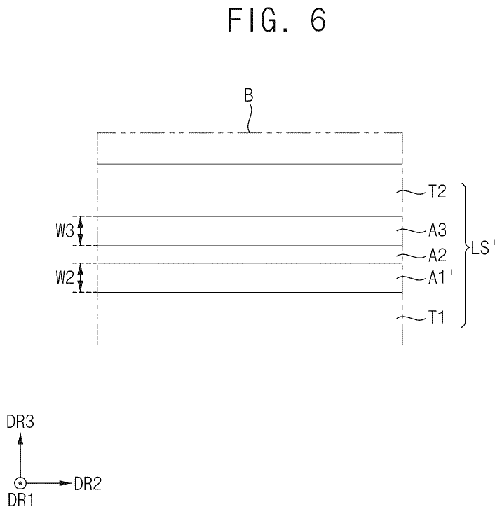

FIG. 6 is an enlarged cross-sectional view of another example of area B of FIG. 3, according to an embodiment.

In another embodiment and referring to FIG. 6, a connecting electrode LS may include a first layer T1, a second layer A1′, a third layer A2, a fourth layer A3, and a fifth layer T2.

In an embodiment, the second layer A1′ may be disposed on the first layer T1. The third layer A2 may be disposed on the second layer A1′. The fourth layer A3 may be disposed on the third layer A2. The fifth layer T2 may be disposed on the fourth layer A3.

In an embodiment, the first layer T1 may include a metal. In an embodiment, the first layer T1 may include titanium. However, this invention is not limited thereto, and in another embodiment, the first layer T1 may include other kinds of metal materials such as tungsten, copper, nickel, chromium, or the like.

In an embodiment, the second layer A1′ may include a metal. In an embodiment, the second layer A1′ may include an aluminum alloy. In an embodiment, the aluminum alloy included in the second layer A1′ may include nickel, neodymium, lanthanum, or the like. These materials may be used alone or in combination with each other.

For example, in an embodiment, the second layer A1′ may include aluminum and nickel. In an embodiment, the aluminum alloy included in the second layer A1 may further include neodymium. In an embodiment, the aluminum alloy included in the second layer A1′ may further include lanthanum. However, this invention is not limited thereto, and the aluminum alloy included in the second layer A1′ may further include other kinds of metal materials.

In an embodiment, the third layer A2 may include a metal. In an embodiment, the third layer A2 may include aluminum. For example, the third layer A2 may include pure aluminum. However, this invention is not limited thereto, and in another embodiment, the third layer A2 may include other kinds of metal materials such as tungsten, copper, nickel, chromium, or the like.

In an embodiment, the fourth layer A3 may include a metal. In an embodiment, the fourth layer A3 may include an aluminum alloy. In an embodiment, the aluminum alloy included in the fourth layer A3 may include nickel, neodymium, lanthanum, or the like. These materials may be used alone or in combination with each other.

For example, in an embodiment, the fourth layer A3 may include aluminum and nickel. In an embodiment, the aluminum alloy included in the fourth layer A3 may further include neodymium. In an embodiment, the aluminum alloy included in the fourth layer A3 may further include lanthanum. However, this invention is not limited thereto, and the aluminum alloy included in the fourth layer A3 may further include other types of metal materials.

In an embodiment, the fourth layer A3 and the second layer A1′ may include substantially the same material. However, this invention is not limited thereto, and in another embodiment, the fourth layer A3 and the second layer A1′ may include different materials.

In an embodiment, the fifth layer T2 may include a metal. In an embodiment, the fifth layer T2 may include titanium. However, this invention is not limited thereto, and in another embodiment, the fifth layer T2 may include other kinds of metal materials such as tungsten, copper, nickel, chromium, or the like.

In an embodiment, a ratio of the nickel in the aluminum alloy included in the second layer A1′ of the connecting electrode LS may be equal to or greater than about 0.02 atomic percent and equal to or less than about 0.05 atomic percent. In an embodiment, a ratio of the neodymium in the aluminum alloy included in the second layer A1′ of the connecting electrode LS′ may be equal to or greater than about 0.02 atomic percent and equal to or less than about 0.05 atomic percent. In an embodiment, a ratio of the lanthanum in the aluminum alloy included in the second layer A1′ of the connecting electrode LS may be equal to or greater than about 0.02 atomic percent and equal to or less than about 0.05 atomic percent.

In an embodiment, a ratio of the nickel in the aluminum alloy included in the fourth layer A3 of the connecting electrode LS′ may be equal to or greater than about 0.02 atomic percent and equal to or less than about 0.05 atomic percent. In an embodiment, a ratio of the neodymium in the aluminum alloy included in the fourth layer A3 of the connecting electrode LS′ may be equal to or greater than about 0.02 atomic percent and equal to or less than about 0.05 atomic percent. In an embodiment, a ratio of the lanthanum in the aluminum alloy included in the fourth layer A3 of the connecting electrode LS may be equal to or greater than about 0.02 atomic percent and equal to or less than about 0.05 atomic percent.

In an embodiment, a thickness W2 of the second layer A1′ of the connecting electrode LS′ may be equal to or greater than about 2000 angstroms and equal to or less than about 3000 angstroms. In an embodiment, a thickness W3 of the fourth layer A3 of the connecting electrode LS′ may be equal to or greater than about 2000 angstroms and equal to or less than about 3000 angstroms.

In an embodiment, the thickness W3 of the fourth layer A3 and the thickness W2 of the second layer A1′ may be substantially the same. However, this invention is not limited thereto, and in another embodiment, the thickness W3 of the fourth layer A3 and the thickness W2 of the second layer A1′ may be different.

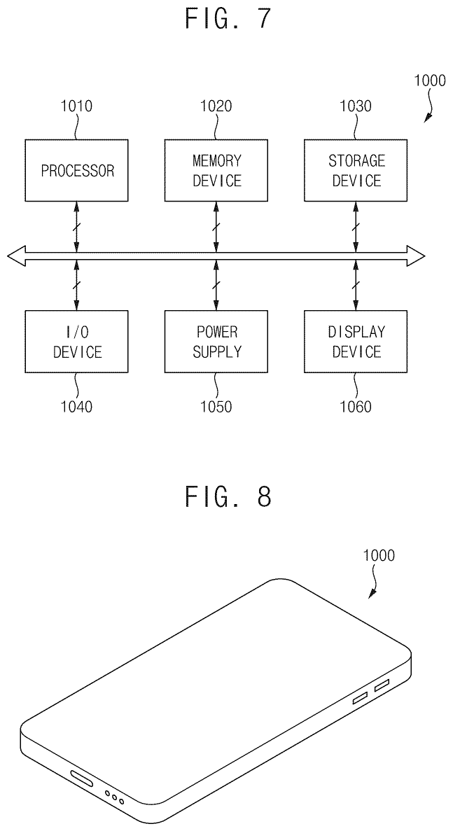

FIG. 7 is a block diagram illustrating an electronic device according to embodiments. FIG. 8 is a diagram illustrating an example in which the electronic device of FIG. 7 is implemented as a smart phone.

Referring to FIGS. 7 and 8, an electronic device 1000 may include a processor 1010, a memory device 1020, a storage device 1030, an input/output device 1040, a power supply 1050, and a display device 1060. In this case, the display device 1060 may be the display device DD of FIG. 1. In addition, the electronic device 1000 may further include several ports capable of communicating with a video card, a sound card, a memory card, a USB device, and/or the like.

According to an embodiment, as illustrated in the FIG. 8, the electronic device 1000 may be implemented as a smartphone. However, this is exemplary, and the electronic device 1000 may be implemented as various devices according to embodiments. For example, the electronic device 1000 may be implemented as a mobile phone, a video phone, a smart pad, a smart watch, a tablet PC, a vehicle navigation device, a computer monitor, a notebook computer, a head mounted display device, and/or the like.

The processor 1010 may be a microprocessor, a central processing unit, an application processor, and/or the like. The processor 1010 may be connected to other components through an address bus, a control bus, a data bus, and/or the like. In an embodiment, the processor 1010 may also be connected to an expansion bus such as a peripheral component interconnect (“PCI”) bus.

The memory device 1020 may store data necessary for operation of the electronic device 1000. For example, the memory device 1020 may include a nonvolatile memory device and/or a volatile memory device. Examples of the nonvolatile memory device may include erasable programmable read-only Memory (“EPROM”) device, electrically erasable programmable read-only memory (“EEPROM”) device, flash memory device, phase change random access memory (“PRAM”) device, resistance random access memory (“RRAM”) device, nano floating gate memory (“NFGM”) device, polymer random access memory (“PoRAM”) device, magnetic random access memory (“MRAM”) device, ferroelectric random access memory (“FRAM”) device, and/or the like. Example of the volatile memory device may include dynamic random access memory (“DRAM”) device, static random access memory (“SRAM”) device, mobile DRAM device, and/or the like.

The storage device 1030 may include a solid state drive (“SSD”), a hard disk drive (“HDD”), a CD-ROM, and/or the like.

The input/output device 1040 may include an input mean such as a keyboard, a keypad, a touch pad, a touch screen, and a mouse, and/or the like, and an output mean such as a speaker and a printer. In an embodiment, the display device 1060 may be included in the input/output device 1040.

The power supply 1050 may supply power necessary for operation of the electronic device 1000. For example, the power supply 1050 may supply power necessary for operation of the display device 1060.

The display device 1060 may be connected to other components through buses or other communication links.

The present invention can be applied to various display devices. For example, the present invention is applicable to various display devices such as display devices for vehicles, ships and aircraft, portable communication devices, display devices for exhibition or information transmission, medical display devices, and the like.

The foregoing is illustrative of embodiments of the invention and is not to be construed as limiting thereof. Although a few embodiments have been described, those skilled in the art will readily appreciate that many modifications are possible in the invention without materially departing from the novel teachings and advantages of the invention. Accordingly, all such modifications are intended to be included within the scope of the invention. Therefore, it is to be understood that the foregoing is illustrative of various embodiments and is not to be construed as limited to the specific embodiments disclosed, and that modifications to the disclosed embodiments, as well as other embodiments, are intended to be included within the scope of the invention. Moreover, the embodiments or parts of the embodiments may be combined in whole or in part without departing from the scope of the invention.

What is claimed is:

1. A display device comprising:
a first base substrate including a display area in which pixels are disposed and a pad area spaced apart from the display area;
an intermediate metal layer disposed on the first base substrate;
a second base substrate disposed on the intermediate metal layer;
a chip on film in contact with the intermediate metal layer in the pad area; and
a connecting electrode disposed on the second base substrate, in contact with the intermediate metal layer in the pad area, and including a first layer including an aluminum alloy and a second layer disposed on the first layer and including aluminum.

2. The display device of claim 1, wherein the aluminum alloy included in the first layer includes nickel (“Ni”).

3. The display device of claim 2, wherein the aluminum alloy included in the first layer further includes neodymium (“Nd”).

4. The display device of claim 3, wherein the aluminum alloy included in the first layer further includes lanthanum (“La”).

5. The display device of claim 4, wherein a ratio of the nickel in the aluminum alloy included in the first layer is equal to or greater than about 0.02 atomic percent and equal to or less than about 0.05 atomic percent.

6. The display device of claim 4, wherein a ratio of the neodymium in the aluminum alloy included in the first layer is equal to or greater than about 0.02 atomic percent and equal to or less than about 0.05 atomic percent.

7. The display device of claim 4, wherein a ratio of the lanthanum in the aluminum alloy included in the first layer is equal to or greater than about 0.02 atomic percent and equal to or less than about 0.05 atomic percent.

8. The display device of claim 1, wherein a thickness of the first layer is equal to or greater than about 3000 angstroms and equal to or less than about 4000 angstroms.

9. The display device of claim 1, wherein the connecting electrode further includes:
a third layer disposed on the second layer and including an aluminum alloy.

10. The display device of claim 9, wherein the aluminum alloy included in the third layer of the connecting electrode includes at least one of nickel, neodymium, and lanthanum.

11. The display device of claim 10, wherein
a ratio of the nickel in the aluminum alloy included in the third layer of the connecting electrode is equal to or greater than about 0.02 atomic percent and equal to or less than about 0.05 atomic percent,
a ratio of the neodymium in the aluminum alloy included in the third layer of the connecting electrode is equal to or greater than about 0.02 atomic percent and equal to or less than about 0.05 atomic percent, and
a ratio of the lanthanum in the aluminum alloy included in the third layer of the connecting electrode is equal to or greater than about 0.02 atomic percent and equal to or less than about 0.05 atomic percent.

12. The display device of claim 9, wherein a thickness of each of the first layer and the third layer is equal to or greater than about 2000 angstroms and equal to or less than about 3000 angstroms.

13. The display device of claim 1, wherein the connecting electrode further includes:
a fourth layer disposed under the first layer and including titanium.

14. The display device of claim 13, wherein the connecting electrode further includes:
a fifth layer disposed on the second layer and including titanium.

15. The display device of claim 1, wherein the first base substrate defines a first opening in a partial area of the pad area, and
the chip on film is in contact with a lower surface of the intermediate metal layer in the first opening.

16. The display device of claim 1, wherein each of the pixels includes:
an active layer disposed on the second base substrate;
a gate electrode disposed on the active layer;
a source electrode disposed on the gate electrode; and
a drain electrode disposed on the gate electrode and spaced apart from the source electrode, wherein
the connecting electrode, the source electrode and the drain electrode are disposed on a same layer.

17. The display device of claim 1, wherein the connecting electrode contacts an upper surface of the intermediate metal layer.

18. The display device of claim 1, wherein the second base substrate includes polyimide.

19. The display device of claim 18, wherein the first base substrate and the second base substrate includes a same material.

20. The display device of claim 1, wherein the second base substrate defines a second opening, and
the connecting electrode contacts the intermediate metal layer in the second opening.

21. An electronic device comprising:
a first base substrate including a display area in which pixels are disposed and a pad area spaced apart from the display area;
an intermediate metal layer disposed on the first base substrate;
a second base substrate disposed on the intermediate metal layer;
a chip on film in contact with the intermediate metal layer in the pad area;
a connecting electrode disposed on the second base substrate, in contact with the intermediate metal layer in the pad area, and including a first layer including an aluminum alloy and a second layer disposed on the first layer and including aluminum; and
a memory device configured to store data.
